(19) United States
(12) Patent Application Publication
(10) Pub. No.: US 2022/0130844 A1
(43) Pub. Date: Apr. 28, 2022

(54) NONVOLATILE SEMICONDUCTOR MEMORY DEVICE

(71) Applicant: ROHM CO., LTD., Kyoto (JP)

(72) Inventors: Tadayuki YAMAZAKI, Kyoto (JP); Yasunobu HAYASHI, Kyoto (JP); Goro SHIMIZU, Kyoto (JP)

(73) Assignee: ROHM CO., LTD., Kyoto (JP)

(21) Appl. No.: 17/569,981

(22) Filed: Jan. 6, 2022

Related U.S. Application Data
(63) Continuation of application No. PCT/JP2020/027087, filed on Jul. 10, 2020.

(30) Foreign Application Priority Data
Aug. 1, 2019 (JP) 2019-142298

(51) Int. Cl. H01L 27/112

(52) U.S. Cl. CPC H01L 27/11206

(57) ABSTRACT

A memory cell formed on the surface of a p-well of a semiconductor substrate includes a drain region and a source region that are formed with a channel region therebetween; an insulating film that is formed to cover the channel region; a gate that is formed on the insulating film; sidewall spacers that are formed to be positioned at side surfaces of the gate and directly above the channel region; a salicide block film that is formed to cover a portion of the drain region, a portion of the source regio, the gat, and the sidewall spacers; a drain salicide layer and a source salicide layer that are formed at the salicide block film and on the drain region and the source region exposed from the salicide block film; and a nitride film that is formed to cover the salicide block film, the drain salicide layer, and the source salicide layer.

### CROSS-REFERENCE TO RELATED APPLICATION

This disclosure is a continuation application of International Application No. PCT/JP2020/027087, filed on Jul. 10, 2020, which claims the priority of Japanese Patent Application No. 2019-142298, filed on Aug. 1, 2019, the entire contents of which are incorporated by reference herein.

### TECHNICAL FIELD

The present disclosure relates to a sidewall charge trapping type of nonvolatile semiconductor memory device.

### BACKGROUND ART

A sidewall charge trapping type of nonvolatile semiconductor memory device has been provided in the past which traps a charge on a sidewall of a gate of a MOS transistor manufactured by means of a CMOS manufacturing process (see, for example, Non-Patent Literature 1). The nonvolatile semiconductor memory device is one-time programmable (OTP) or multiple-time programmable (MTP).

FIG. 1 is a cross sectional view showing an example of the structure of a memory cell 110 of a conventional sidewall charge trapping type of OTP or MTP nonvolatile semiconductor memory device. The memory cell 110 is formed on a p-well 111 of a substrate. In the memory cell 110, a gate 116 is formed on an insulating film 115 which covers a channel region 112 interposed between a drain region 113 and a source region 114. Sidewall spacers 117 made of a nitride are formed at side surfaces of the gate 116 and directly above the channel region 112 via the insulating film 115, which extends also to the side surfaces of the gate 116. Salicide layers 120 are formed on the upper surface of the gate 116, and on the surfaces of the drain region 113 and the source region 114, individually. A nitride film 119 is formed so as to cover the gate 116 and the sidewall spacers 117 and extend to the drain region 113 and the source region 114. In the memory cell 110, a charge is injected and held in the sidewall spacers 117, which face the source region 114 from the source region 114. In this example, a description has been given for a p-channel, but the same applies to an n-channel.

### CITATION LIST

### Non-Patent Literature

[Non-patent literature 1] M. Fukuda and others, IEEE Electron device letter, Vol. 24, 2003, “New nonvolatile memory with charge trapping sidewall”

### SUMMARY

### Problem to be Solved

However, in the conventional sidewall charge trapping type of OTP or MTP nonvolatile semiconductor memory device as shown in FIG. 1, the amount of charge held by the sidewall spacers 117 of the memory cell 110 gradually decreases according to the elapse of time, and there was a case where stored data was lost. There was a case where data was lost in 10 years when the device was used in an 80 ° C. automotive environment, for example.

The present disclosure has been proposed in view of the above described problem, and an object of the present disclosure is to provide a sidewall charge trapping type of OTP or MTP nonvolatile semiconductor memory device with enhanced charge holding characteristics, which can hold stored data for a long period of time.

### Means for Solving the Problem

In order to solve the above described problem, a nonvolatile semiconductor memory device according to the present application includes one or more memory cells formed on a surface of a semiconductor substrate. The memory cells include: a source region and a drain region that are formed with a channel region therebetween; an insulating film that is formed to cover the channel region; a gate that is formed on the insulating film; a sidewall spacer that is formed to be positioned at a side surface of the gate and directly above the channel region; a salicide block film that is formed to cover a portion of the source region, a portion of the drain region, the gate, and the sidewall spacer; a salicide layer that is formed at the salicide block film and on the source region and the drain region exposed from the salicide block film; and a nitride film that is formed to cover the salicide block film and the salicide layer.

The salicide block film may be an oxide film with a thickness of 50 nm or more. The device may further include a contact that is formed outside the salicide block film and directly above the salicide layer. The sidewall spacer may hold a charge introduced from the source region.

The nonvolatile semiconductor memory device may further include: one or more MOS transistors formed on the surface of the semiconductor substrate. The MOS transistors include: a source region and a drain region that are formed with a channel region therebetween; an insulating film that is formed to cover the channel region; a gate that is formed on the insulating film; a sidewall spacer that is formed to be positioned at a side surface of the gate and directly above the channel region; a salicide layer that is formed on the source region, the drain region, and the gate; and a nitride film that is formed to cover the salicide layer and the sidewall spacer.

The insulating film of the MOS transistor and the insulating film of the memory cell may have the same thickness. The gate of the MOS transistor and the gate of the memory cell may have the same height and width. The sidewall spacer of the MOS transistor and the sidewall spacer of the memory cell may have the same height and width.

### Effects

According to the present disclosure, the movement of a charge injected into sidewall spacers is prevented by a salicide block film which is made of an oxide and covers the sidewall spacers. Therefore, a charge is stably held in the sidewall spacers and charge holding characteristics are enhanced. Accordingly, data stored in a nonvolatile semiconductor memory device can be maintained for a long period of time.

### BRIEF DESCRIPTION OF THE DRAWINGS

FIG. 1 is a cross sectional view showing the schematic structure of a memory cell of a conventional nonvolatile semiconductor memory device.

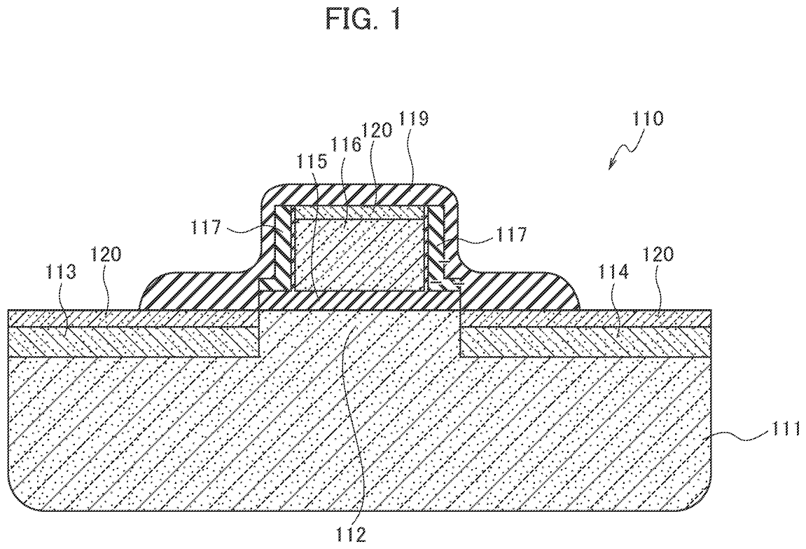

FIG. 2 is a cross sectional view showing the schematic structure of a memory cell of a nonvolatile semiconductor memory device of the present embodiment.

FIG. 3 is a cross sectional view showing an example of the structure of a memory cell of a nonvolatile semiconductor memory device of the present embodiment.

FIGS. 4A to 4C are process flow diagrams of a memory cell of a nonvolatile semiconductor memory device of the present embodiment.

FIGS. 5A to 5C are process flow diagrams of a memory cell of a nonvolatile semiconductor memory device of the present embodiment.

FIGS. 6A and 6B are process flow diagrams of a memory cell of a nonvolatile semiconductor memory device of the present embodiment.

FIG. 7 is a cross sectional view showing a modified example of a nonvolatile semiconductor memory device of the present embodiment.

FIG. 8 is a circuit diagram schematically showing a circuit of a memory cell of a nonvolatile semiconductor memory device of the present embodiment.

### EMBODIMENTS

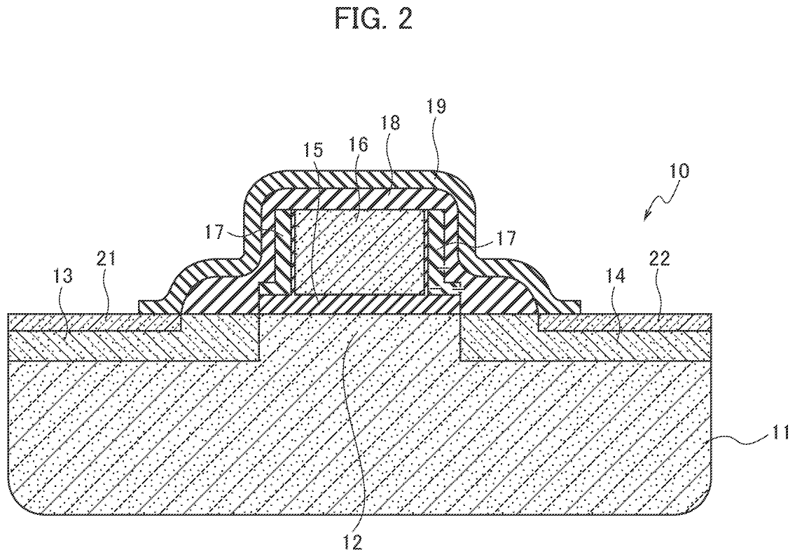

Next, an embodiment of a nonvolatile semiconductor memory device will be described with reference to the drawings. FIG. 2 is a cross sectional view schematically showing the structure of a memory cell 10 of a nonvolatile semiconductor memory device according to the present embodiment. The nonvolatile semiconductor memory device of the present embodiment is a sidewall charge trapping type of nonvolatile semiconductor memory device that traps a charge on the sidewall of a gate of a MOS transistor manufactured by means of a CMOS manufacturing process. The nonvolatile semiconductor memory device is OTP or MTP. In the present embodiment, the structure of a p-channel is exemplified, but the description thereof can be similarly applied to the structure of an n-channel.

The memory cell 10 is formed on the surface of a p-well 11 which is a doped well in which a p-type impurity is doped in a silicon semiconductor substrate. On the surface of the p-well 11, a drain region 13 and a source region 14 in which an n-type impurity is doped are formed with a channel region 12 therebetween. An insulating film 15 made of an oxide (SiO₂) that covers the channel region 12 is formed. A polysilicon gate 16 with a substantially rectangular cross section is formed on the insulating film 15. The insulating film 15 extends so as to also cover the side surfaces of the gate 16. Sidewall spacers 17 made of a nitride (SiN) are formed on the side surfaces of the gate 16 and directly above the channel region 12 via the insulating film 15. The sidewall spacers 17, which face the source region 14, serve to hold a charge injected from the source region 14.

A salicide block film 18 made of an oxide (SiO₂) is formed. The salicide block film 18 covers the gate 16, the sidewall spacers 17, a portion that is a part of the drain region 13 and is adjacent to the channel region 12, and a portion that is a part of the source region 14 and is adjacent to the channel region 12. A drain salicide layer 21 is formed on the surface of a portion of the drain region 13 exposed from the salicide block film 18. The drain salicide layer 21 is made of, for example, salicide with titanium, cobalt, or nickel (TiSi, CoSi, or NiSi). Similarly, a source salicide layer 22 is formed on the surface of a portion of the source region 14 exposed from the salicide block film 18. A nitride film 19 made of a nitride (SiN) is formed to cover the salicide block film 18, and the drain salicide layer 21 and the source salicide layer 22, which are exposed from the salicide block film 18. The nitride film 19 is removed from portions where contacts are connected of the drain salicide layer 21 and the source salicide layer 22.

In the present embodiment, the sidewall spacers 17 of the memory cell 10 are covered with the salicide block film 18 made of an oxide (SiO₂). The salicide block film 18 may have a thickness of 50 nm or more. The movement of a charge injected into the sidewall spacers 17 from the source region 14 is prevented by the salicide block film 18 made of an oxide. Therefore, a charge is stably held in the sidewall spacers 17. The surfaces of the sidewall spacers 17 that face the channel region 12 and the gate 16 are also covered with the insulating film 15 made of an oxide. Accordingly, in the present embodiment, a charge is stably held in the sidewall spacers 17 to improve the charge holding characteristic, and data is held for a long period of time. For example, data can be held for at least 20 years in a 150° C. temperature environment when the present disclosure is used in an automobile.

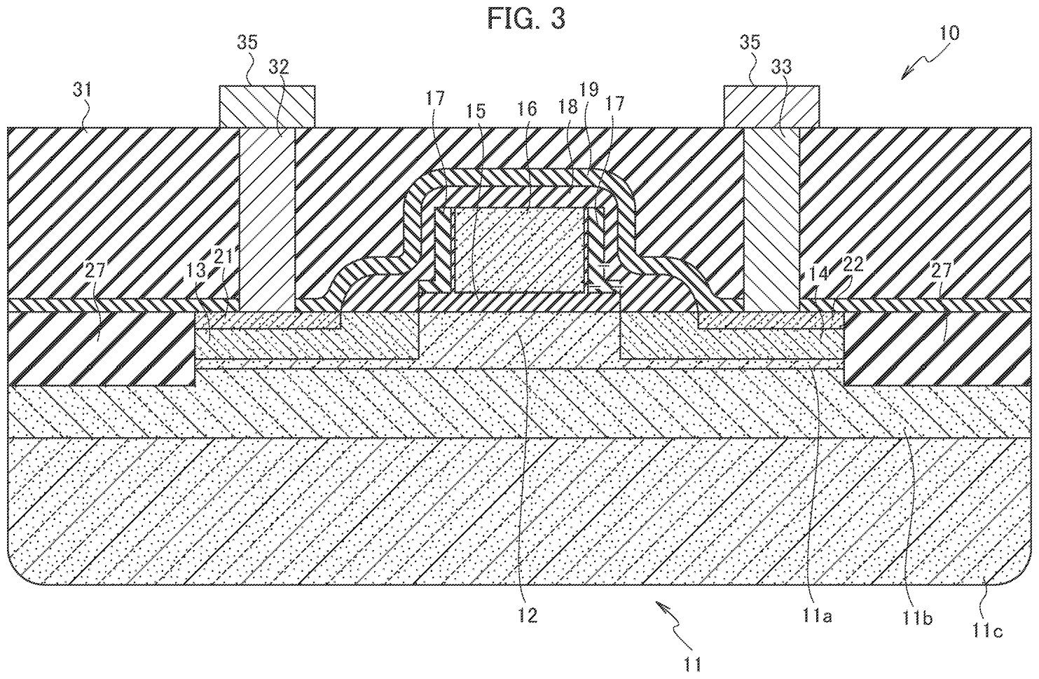

FIG. 3 is a cross sectional view showing an example of the structure of a memory cell 10 of a nonvolatile semiconductor memory device of the present embodiment. FIG. 3 shows more specifically the structure of the memory cell 10 in the nonvolatile semiconductor memory device shown in FIG. 2.

The memory cell 10 is formed on the surface of the p-well 11 of a silicon semiconductor substrate. The p-well 11 may include a p-body 11a, a low-voltage p-well 11b, and a high-voltage p-well 11c which are formed in this order from the surface in the depth direction. Element isolation insulating layers 27 made of an oxide (SiO₂) are formed on the surface of the p-well 11.

On the surface of the p-body 11a, a drain region 13 and a source region 14 in which an n-type impurity is doped are formed with a channel region 12 therebetween. An insulating film 15 that is made of an oxide (SiO₂) and covers the channel region 12 is formed. A polysilicon gate 16 with a substantially rectangular cross section is formed on the insulating film 15. The insulating film 15 extends so as to also cover the side surfaces of the gate 16. Sidewall spacers 17 made of a nitride (SiN) are formed on the side surfaces of the gate 16 and directly above the channel region 12 via the insulating film 15.

A salicide block film 18 made of an oxide (SiO₂) is formed. The salicide block film 18 covers the gate 16, the sidewall spacers 17, a portion that is a part of the drain region 13 and is adjacent to the channel region 12, and a portion that is a part of the source region 14 and is adjacent to the channel region 12. A drain salicide layer 21 is formed on the surface of a portion of the drain region 13 exposed from the salicide block film 18. The drain salicide layer 21 is made of, for example, salicide with cobalt (CoSi). Similarly, a source salicide layer 22 is formed on the surface of a portion of the source region 14 exposed from the salicide block film 18.

A nitride film 19 made of a nitride (SiN) is formed. The nitride film 19 covers the salicide block film 18, the drain salicide layer 21 and the source salicide layer 22 exposed from the salicide block film 18, and the element isolation insulating layers 27. An interlayer insulating film 31 made of an oxide (SiO₂) is formed to a predetermined height and covers the nitride film 19. A flat surface is formed on the top of the interlayer insulating film 31. A drain contact 32 is formed directly above the drain salicide layer 21. The drain contact 32 passes through the nitride film 19 and the interlayer insulating film 31. The drain contact 32 is connected to the wiring 35 formed on the surface of the interlayer insulating film 31. Further, a source contact 33 is formed directly above the source salicide layer 22. The source contact 33 passes through the nitride film 19 and the interlayer insulating film 31. The drain contact 32 is connected to the wiring 35 formed on the surface of the interlayer insulating film 31.

In the present embodiment, the drain contact 32 and the source contact 33 of the memory cell 10 are formed directly above the drain salicide layer 21 of the drain region 13 and the source salicide layer 22 of the source region 14, respectively. The drain salicide layer 21 and the source salicide layer 22 are positioned outside an active portion of the memory cell 10, the active portion including the gate 16 and the sidewall spacers 17 and being surrounded by the salicide block film 18. Therefore, the active portion of the memory cell 10 surrounded by the salicide block film 18 is not damaged by the drain contact 32 or the source contact 33. Accordingly, stable operation of the memory cell 10 can be ensured.

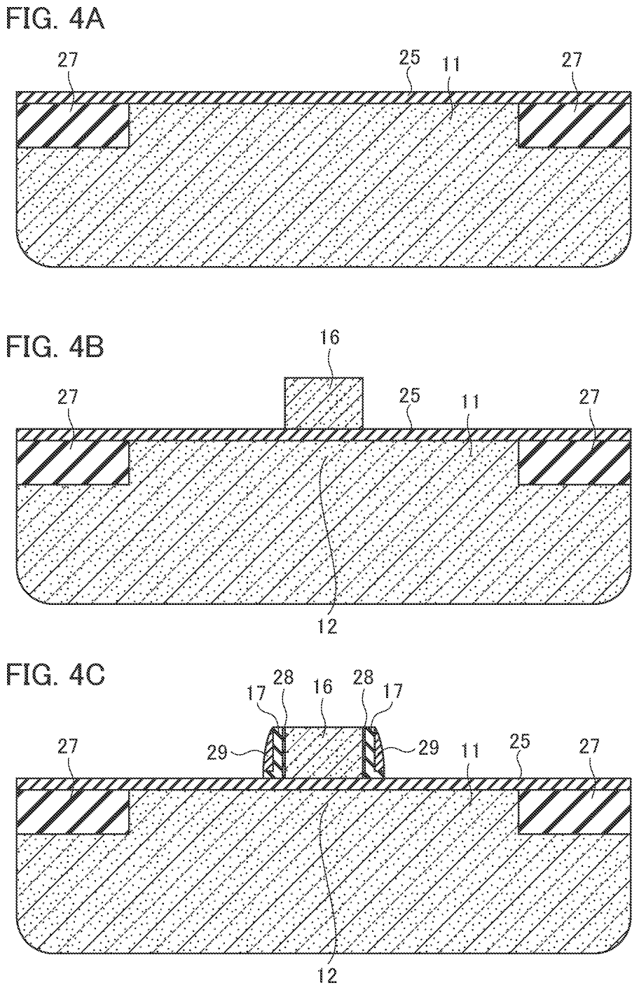

FIGS. 4A to 6B are process flow diagrams of the memory cell 10 of the nonvolatile semiconductor memory device of the present embodiment. In the process shown in FIG. 4A, there is a region for forming the memory cell 10 defined on the surface of a silicon semiconductor substrate, the surface of the region is covered with a first oxide film 25, and the region is separated by the element isolation insulating layers 27. A p-well 11 is formed by injecting a p-type impurity into this region.

In the process shown in FIG. 4B, polysilicon is deposited on the p-well 11 formed in the process of FIG. 4A to form a gate 16. The gate 16 is formed above the channel region 12 of the p-well 11 via the first oxide film 25. In the process shown in FIG. 4C, sidewall spacers 17 made of a nitride (SiN) are formed at the side surfaces of the gate 16 formed in the process shown in FIG. 4B. The sidewall spacers 17 are formed at the side surfaces of the gate 16 so as to cover second oxide films 28 formed in advance. Further, third oxide films 29 are formed so as to cover the sidewall spacers 17.

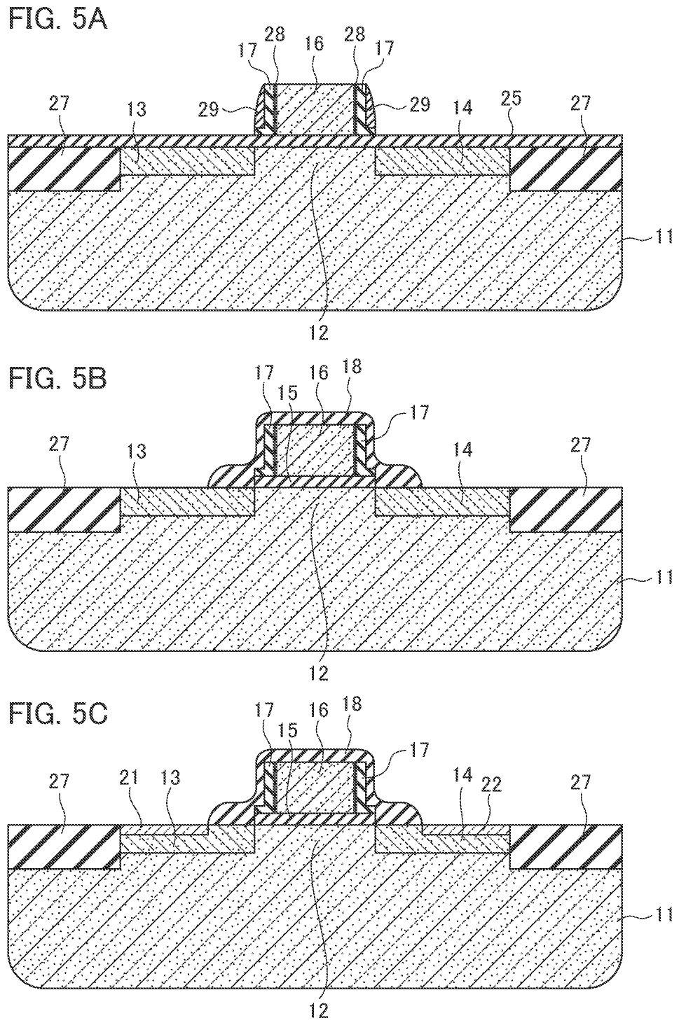

The process shown in FIG. 5A follows the process of forming the sidewall spacers 17 shown in FIG. 4B. In the process shown in FIG. 5A, an n-type impurity is injected into predetermined ranges of the surface of the p-well 11. Accordingly, a drain region 13 and a source region 14 are formed with a channel region 12 therebetween. The process shown in FIG. 5B follows the process of forming the drain region 13 and the source region 14 shown in FIG. 5A. In the process shown in FIG. 5B, a salicide block film 18 made of an oxide (SiO₂) is formed. The salicide block film 18 covers the gate 16, the sidewall spacers 17, a portion that is a part of the drain region 13 and is adjacent to the sidewall spacers 17, and a portion that is a part of the source region 14 and is adjacent to the sidewall spacers 17. The salicide block film 18 may have a thickness of 50 nm or more. The salicide block film 18 is integrated with the first oxide film 25 that covers the surface of the p-well 11, second oxide films 28 that cover the side surfaces of the gate 16, and third oxide films 29 that cover the sidewall spacers 17. A portion of the first oxide film 25 covering the surface of the p-well 11 positioned outside the salicide block film 18 is removed. The portion of the first oxide film 25 below the gate 16, which is also referred to as a gate insulating film, and the second oxide films 28 that cover the side surfaces of the gate 16 form the insulating film 15, which is shown in the cross sectional view of FIG. 2 or FIG. 3 showing the structure of the memory cell of the nonvolatile semiconductor memory device of the present embodiment.

The process shown in FIG. 5C follows the process of forming the salicide block film 18 shown in FIG. 5B. In the process shown in FIG. 5C, a drain salicide layer 21 is formed on a portion of the drain region 13 of the p-well 11 exposed from the salicide block film 18. The drain salicide layer 21 is made of salicide with titanium, cobalt, or nickel (TiSi, CoSi, or NiSi). Similarly, a source salicide layer 22 is formed on a portion of the source region 14 of the p-well 11 exposed from the salicide block film 18. The salicide block film 18 covers a portion that is a part of the drain region 13 and is adjacent to the channel region 12 and a portion that is a part of the source region 14 and is adjacent to the channel region 12. Accordingly, the formation of a salicide layer is prevented by the salicide block film 18.

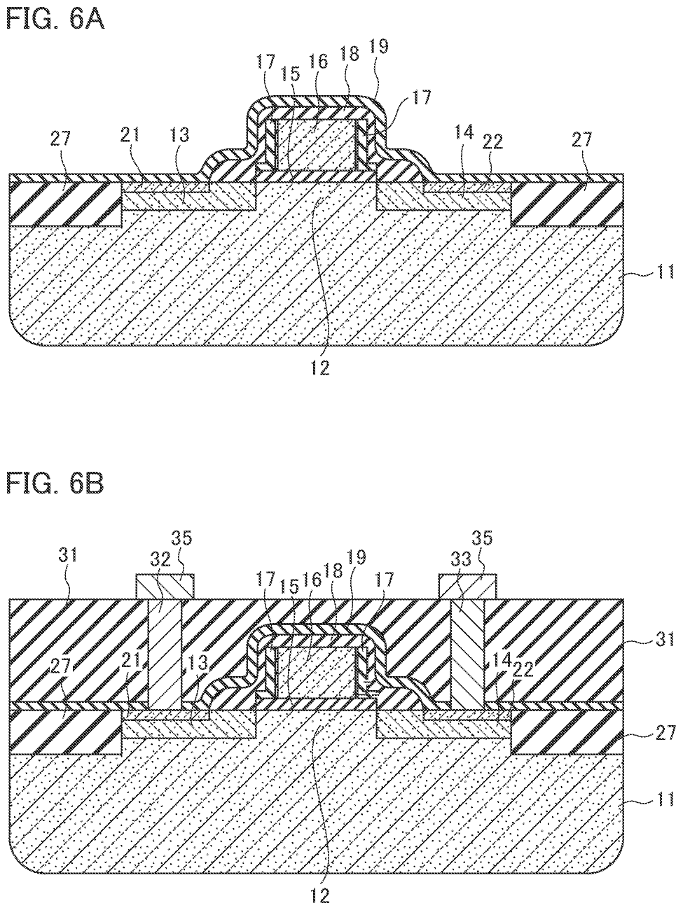

The process shown in FIG. 6A follows the process of forming the drain salicide layer 21 and the source salicide layer 22 shown in FIG. 5C. In the process shown in FIG. 6A, a nitride film 19 made of a nitride (SiN) is formed so as to cover the entire salicide block film 18, the drain salicide layer 21, the source salicide layer 22, and the element isolation insulating layers 27. In the process shown in FIG. 6B, an interlayer insulating film 31 made of an oxide (SiO₂) is formed to a predetermined height on the nitride film 19 formed in the process shown in FIG. 6A. A drain contact 32 is formed directly above the drain salicide layer 21. The drain contact 32 passes through the nitride film 19 and the interlayer insulating film 31. Similarly, a source contact 33 is formed directly above the source salicide layer 22. The source contact 33 passes through the nitride film 19 and the interlayer insulating film. The wiring 35 connected to upper ends of the drain contact 32 and the source contact 33 is formed on the surface of the interlayer insulating film 31.

In the present embodiment, except for the process of forming the salicide block film 18 shown in FIG. 5B, the manufacturing process is the same as that of a general sidewall charge trapping type of OTP or MTP nonvolatile semiconductor memory device. Therefore, the present embodiment can be easily realized by adding the process of forming the salicide block film 18 to a general manufacturing process.

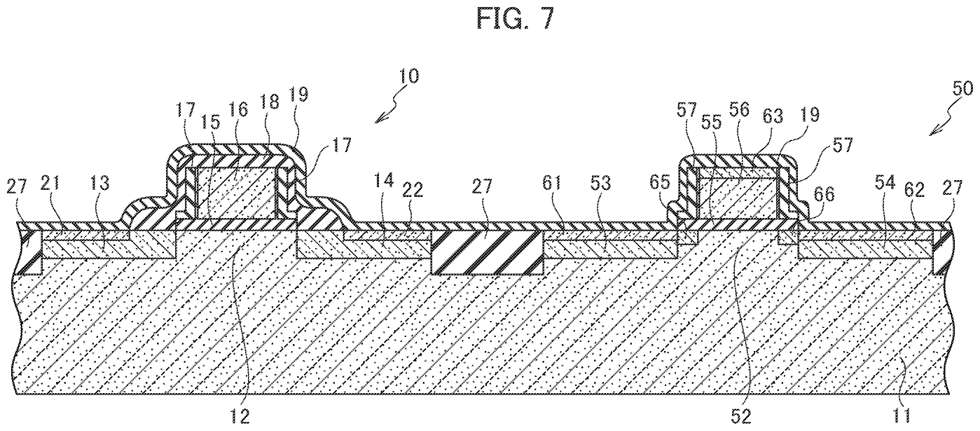

FIG. 7 is a sectional view showing a modified example of a nonvolatile semiconductor memory device of the present embodiment. In the modified example, the memory cell 10 shown in FIG. 2 is formed on the surface of a silicon semiconductor substrate, and a MOS transistor 50 is formed adjacent to the memory cell 10, the MOS transistor 50 being for driving the memory cell 10. In the modified example, components common to those of the memory cell 10 shown in FIG. 2 are denoted by the same reference numerals and the description thereof is omitted.

The MOS transistor 50 and the memory cell 10 are formed on the same surface of the p-well 11. The MOS transistor 50 is formed adjacent to the memory cell 10 with the element isolation insulating layers 27 being interposed therebetween. On the surface of the p-well 11, a drain region 53 and a source region 54 in which an n-type impurity is doped are formed with a channel region 52 therebetween. From the drain region 53 and the source region 54, lightly doped drain (LDD) regions 65 and 66 are formed toward the channel region 52, respectively. An insulating film 55 made of an oxide (SiO₂) is formed to cover the channel region 52. A polysilicon gate 56 with a substantially rectangular cross section is formed on the insulating film 55. Sidewall spacers 57 made of a nitride (SiN) are formed at the side surfaces of the gate 56 and directly above the channel region 52 via the insulating film 55, which also extends to the side surfaces of the gate 56.

On the surfaces of the drain region 53 and the source region 54, a drain salicide layer 61 and a source salicide layer 62 are formed respectively. The drain salicide layer 61 and the source salicide layer 62 are made of salicide with titanium, cobalt, or nickel (TiSi, CoSi, or NiSi), for example. A gate salicide layer 63 is similarly formed on the upper surface of the gate 56. A nitride film 19 made of a nitride (SiN) is formed to cover the drain salicide layer 61, the source salicide layer 62, the gate salicide layer 63, and the sidewall spacers 57. The nitride film 19 also covers the structures of the element isolation insulating layers 27 and the adjacent memory cell 10.

The MOS transistor 50 is the same as the adjacent memory cell 10 except that the MOS transistor 50 does not include the salicide block film 18 and includes the gate salicide layer 63 and lightly doped drain (LDD) regions 65 and 66. Therefore, the MOS transistor 50 can be manufactured by using the manufacturing process of the memory cell 10. The sidewall spacers 57 of the MOS transistor 50 can be formed by using, for example, the forming process of the sidewall spacers 17 of the memory cell 10 shown in FIG. 4C. The drain region 53 and the source region 54 of the MOS transistor 50 can be formed by using the forming process of the drain region 13 and the source region 14 of the memory cell 10 shown in FIG. 5A. The drain salicide layer 61, the source salicide layer 62, the gate salicide layer 63, and the sidewall spacers 57 of the MOS transistor 50 can be formed by using the forming process of the drain salicide layer 21 and the source salicide layer 22 of the memory cell 10 shown in FIG. 5C.

As described above, the memory cell 10 and the MOS transistor 50 can be manufactured at the same time by using a common process. Therefore, a nonvolatile semiconductor memory device of the modified example that includes the memory cell 10 and the MOS transistor 50 can be manufactured with an increase in the number of manufacturing processes being suppressed. Accordingly, the manufacturing cost can be suppressed.

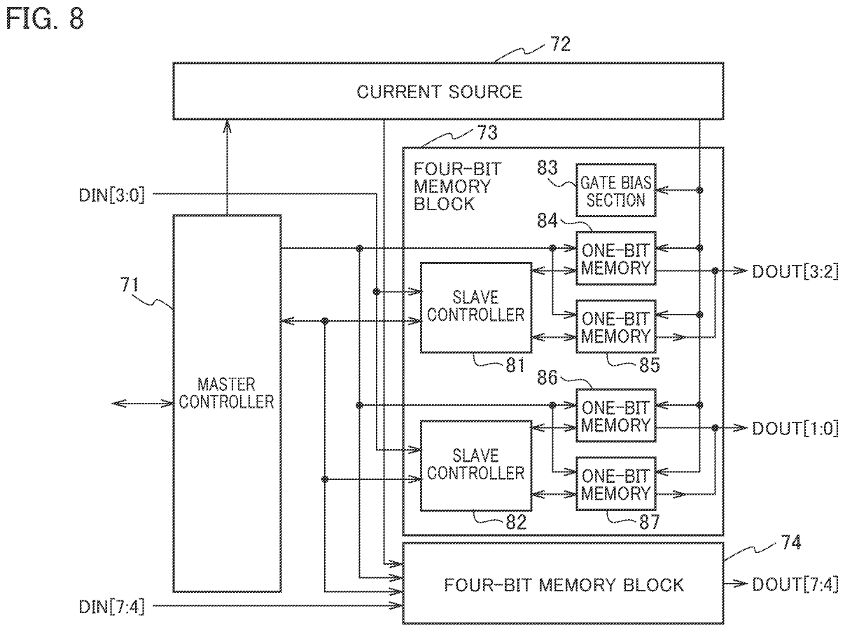

FIG. 8 is a circuit diagram schematically showing a circuit of the nonvolatile semiconductor memory device of the present embodiment. A circuit of the nonvolatile semiconductor memory device includes a master controller 71 that controls the entire device, a current source 72 that supplies a constant current, and a first four-bit memory block 73 and a second four-bit memory block 74 that each include the memory cell 10. The first four-bit memory block 73 includes a first slave controller 81 that controls the first four-bit memory block 73 under the control by the master controller 71, a second slave controller 82, a gate bias section 83 that supplies a bias to a gate, a first one-bit memory 84, a second one-bit memory 85, a third one-bit memory 86, and a fourth one-bit memory 87. The first one-bit memory 84, the second one-bit memory 85, the third one-bit memory 86, and the fourth one-bit memory 87 may each include the configuration of the memory cell 10 shown in FIG. 7, a transistor for driving the memory cell 10, and the like. The second four-bit memory block 74 may have the same configuration as the first four-bit memory block 73. In the example shown above, for the two four-bit memory blocks, each memory block includes four one-bit memories. However, the number of one-bit memories and four-bit memory blocks is not limited to this. For example, it is enough if the number of one-bit memories corresponding to the memory cell 10 is one or more. Such a circuit may be formed on one semiconductor substrate.

In the nonvolatile semiconductor memory device of the present embodiment, the memory cell 10 included in each memory element performs data write, read, and erase operations under the control by the master controller 71 and the corresponding slave controller. In the memory cell 10 shown in FIG. 2, during data write, read, and erase operations, voltages as shown in Table 1 are applied to a substrate including the p-well 11, the drain region 13, the gate 16, and the source region 14.

TABLE 1

| | Source | Drain | Gate | | Substrate |
|---|---|---|---|---|---|
| Write | 5 V | 0 V | 5 | V | 0 V |
| Read | 0 V | 0.5 V | ~1 | V | 0 V |
| Erase | 5 V | 0 V | −5 | V | 0 V |

The memory cell 10 operates according to the voltages shown in Table 1. In the write operation, a charge is injected to the sidewall spacers 17 that face the source region 14 from the source region 14. In the read operation, it is determined whether a charge is held by the sidewall spacers 17 that face the source region 14 based on the current flowing through the channel region 12. In the erase operation, a charge held by the sidewall spacers 17 that face the source region 14 is pulled out into the source region 14. In the example shown in Table 1, the data write, read, and erase operations are possible, and therefore the device is MTP. If only write and read operations are possible, the device is OTP.

### INDUSTRIAL APPLICABILITY

The present disclosure can be used for a control circuit mounted in an automobile such as an ECU, for example.

What is claimed is:

1. A nonvolatile semiconductor memory device comprising: one or more memory cells formed on a surface of a semiconductor substrate, wherein
the memory cells comprise:
a source region and a drain region that are formed with a channel region therebetween;
an insulating film that is formed to cover the channel region;
a gate that is formed on the insulating film;
a sidewall spacer that is formed to be positioned at a side surface of the gate and directly above the channel region;
a salicide block film that is formed to cover a portion of the source region, a portion of the drain region, the gate, and the sidewall spacer;
a salicide layer that is formed at the salicide block film and on the source region and the drain region exposed from the salicide block film; and
a nitride film that is formed to cover the salicide block film and the salicide layer.

2. The nonvolatile semiconductor memory device according to claim 1, wherein the salicide block film is an oxide film with a thickness of 50 nm or more.

3. The nonvolatile semiconductor memory device according to claim 1, further comprising:
a contact that is formed outside the salicide block film and directly above the salicide layer.

4. The nonvolatile semiconductor memory device according to claim 1, wherein the sidewall spacer holds a charge introduced from the source region.

5. The nonvolatile semiconductor memory device according to claim 1, further comprising:
one or more MOS transistors formed on the surface of the semiconductor substrate, wherein
the MOS transistors comprise:
a source region and a drain region that are formed with a channel region therebetween;
an insulating film that is formed to cover the channel region;
a gate that is formed on the insulating film;
a sidewall spacer that is formed to be positioned at a side surface of the gate and directly above the channel region;
a salicide layer that is formed on the source region, the drain region, and the gate; and
a nitride film that is formed to cover the salicide layer and the sidewall spacer.

6. The nonvolatile semiconductor memory device according to claim 5, wherein the insulating film of the MOS transistor and the insulating film of the memory cell have the same thickness.

7. The nonvolatile semiconductor memory device according to claim 5, wherein
the gate of the MOS transistor and the gate of the memory cell have the same height and width.

8. The nonvolatile semiconductor memory device according to claim 5, wherein
the sidewall spacer of the MOS transistor and the sidewall spacer of the memory cell have the same height and width.

9. The nonvolatile semiconductor memory device according to claim 2, further comprising:
a contact that is formed outside the salicide block film and directly above the salicide layer.

10. The nonvolatile semiconductor memory device according to claim 2, wherein the sidewall spacer holds a charge introduced from the source region.

11. The nonvolatile semiconductor memory device according to claim 3, wherein the sidewall spacer holds a charge introduced from the source region.

12. The nonvolatile semiconductor memory device according to claim 9, wherein the sidewall spacer holds a charge introduced from the source region.
